(19) United States
(12) Patent Application Publication
(10) Pub. No.: US 2007/0132476 A1
(43) Pub. Date: Jun. 14, 2007

(54) Method of forming circuit pattern on printed circuit board

(75) Inventor: Duck Young Maeng, Gyeonggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/635,543

(22) Filed: Dec. 8, 2006

(30) Foreign Application Priority Data
Dec. 8, 2005 (KR) 10-2005-0119738

(51) Int. Cl. G01R 31/26

(52) U.S. Cl. 324/765

(57) ABSTRACT

Disclosed is a method of forming a circuit pattern on a printed circuit board. More particularly, this invention relates to a method of forming a circuit pattern on a printed circuit board, including filling a grooved plate having grooves corresponding to a desired circuit pattern in the surface thereof with a conductive material and then bringing portions of the grooved plate sequentially into contact with the surface of the base substrate on which a circuit pattern is formed, to thus transfer the conductive material from the grooves to the surface of the base substrate, consequently forming the circuit pattern. Thereby, according to the method of this invention, a fine circuit pattern and a light, slim, short and small product, as well as a simple process, can be realized.

### CROSS REFERENCE TO RELATED APPLICATION(S)

This application claims the benefit of Korean Patent Application No. 10-2005-0119738, filed Dec. 8, 2005, entitled “Method of forming for circuit on Printed Circuit Board”, which is hereby incorporated by reference in its entirety into this application.

### BACKGROUND OF THE INVENTION

1. Field of the Invention

The present invention relates, in general, to a method of forming a circuit pattern on a printed circuit board (PCB), and more particularly, to a method of forming a circuit pattern on a PCB, capable of forming the circuit pattern using a grooved plate having grooves in the surface thereof corresponding to the desired circuit pattern.

2. Description of the Related Art

Generally, the term “PCB” refers to a printed wiring board for forming conductors on an insulating substrate, based on a circuit design for electrical wiring between electronic components. Further, a PCB is a flat plate of insulating material, made by attaching copper foil to the surface of an insulating substrate formed of phenol resin or epoxy resin, and then performing an etching process depending on a wiring circuit pattern to thus form a desired circuit, in order to densely mount various electrical and electronic components, such as ICs, condensers, and resistors thereon. That is, circuits for interconnecting electronic components are formed in a wiring pattern on the surface of the insulating substrate. The PCB is classified into a single-sided board, a double-sided board, and a multilayered board, depending on the number of wiring circuit board surfaces. As the number of layers is increased, the ability to mount components increases, and more highly precise products can be realized.

The single-sided PCB, composed mainly of a phenol base substrate, is applied to products, such as simple home appliances including TV sets, radio sets, audio devices, or telephones, and measuring instruments, the circuitry of which is not complicated. In comparison, the double-sided PCB, composed mainly of an epoxy resin base substrate, is applied to products, such as color TV sets, VTRs, or facsimiles, the circuitry of which is relatively complicated. Furthermore, the multilayered PCB is applied to highly precise apparatuses, such as 32 bit or more computers, electronic switching systems, and high performance communication apparatuses.

With the trend toward miniaturization and multi-functionality of electronic apparatuses, the resistor or condenser mounted on the board is required to be manufactured in a very small size in order to serve as a device for the multilayered PCB. Accordingly, there is a need for various techniques for forming finer and more precise wiring circuits on PCBs to realize a high degree of integration.

FIGS. 1A to 1D illustrate the conventional process of forming a circuit pattern on a PCB.

As illustrated in FIG. 1A, a copper clad laminate (CCL) 10 having an insulating layer 11 and copper foils 12 formed on both surfaces thereof is provided.

As illustrated in FIG. 1B, through holes 13 are formed through the CCL 10.

In such a case, the through hole 13, which is responsible for electrically connecting the circuit patterns formed on both surfaces of the CCL 10, may be formed through mechanical drilling.

As illustrated in FIG. 1C, a plating layer 14 is formed on the copper foil and the inner wall of the through hole 13 to impart conductivity thereto.

As illustrated in FIG. 1D, the copper foil 12 having the plating layer 14 is formed into a circuit pattern 15.

Such a circuit pattern 15 may be formed through photolithography including applying a photosensitive material (not shown) on the upper surface of the copper foil 12 having the plating layer 14, attaching an artwork film (not shown) having a predetermined pattern, performing exposure and development to thus form an etching resist pattern (not shown), and performing an etching process.

In this case, the circuit patterns 15 formed on both surfaces of the insulating layer 11 may be electrically connected to each other by the through hole 13 having the plating layer 14.

As mentioned above, according to the conventional method of forming the circuit pattern on the PCB, in order to form the circuit pattern, a sequence of applying the photosensitive material on the upper surface of a metal layer on which a circuit pattern is formed, performing exposure and development using an artwork film to thus form an etching resist pattern, performing an etching process, removing the etching resist pattern, and performing a washing process for the etchant should be carried out Therefore, the number of processes required in order to form the circuit pattern is high, resulting in increased manufacturing costs and decreased product competitiveness.

Further, when the etching process is conducted, defect rates are increased due to over-etching or under-etching of the metal layer for forming the circuit pattern, negatively affecting the reliability of the product.

### SUMMARY OF THE INVENTION

Accordingly, the present invention has been made keeping in mind the above problems occurring in the prior art, and an object of the present invention is to provide a method of forming a circuit pattern on a PCB, capable of increasing the reliability of a product while realizing a simple process.

In order to accomplish the above object, the present invention provides a method of forming a circuit pattern on a PCB, comprising (A) providing a base substrate, (B) providing a grooved plate having grooves corresponding to a predetermined circuit pattern in a surface thereof, (C) filling the grooves of the grooved plate with a conductive material, and (D) bringing the grooved plate into contact with the surface of the base substrate to thus transfer the conductive material from the grooves, consequently forming the circuit pattern.

In the method of the present invention, the base substrate may comprise an insulating layer having a predetermined surface roughness thereon, so that the conductive material is easily transferred thereto.

In addition, in the method of the present invention, the base substrate may comprise a seed layer thereon, so that the conductive material is easily transferred thereto.

In addition, in the method of the present invention, the seed layer may be formed through electroless plating.

In addition, in the method of the present invention, the grooved plate may be formed using a material having strength greater than the base substrate.

In addition, in the method of the present invention, the grooved plate may be in the shape of a cylinder.

In addition, in the method of the present invention, the grooved plate may be in the shape of a flat plate.

In addition, in the method of the present invention, the conductive material may be liquid containing metal particles.

In addition, the method of the present invention may further comprise (E) drying the circuit pattern formed on the base substrate, after (D).

In addition, in the method of the present invention, the grooves of the grooved plate in (B) may be formed through an etching process.

Alternatively, in the method of the present invention, the grooves of the grooved plate in (B) may be formed through a physical process.

Alternatively, in the method of the present invention, the grooves of the grooved plate in (B) may be formed through a laser process.

In addition, in the method of the present invention, (D) may be performed by applying predetermined heat and/or pressure to the grooved plate to thus easily transfer the conductive material from the grooves to at least one surface of the base substrate.

### BRIEF DESCRIPTION OF THE DRAWINGS

FIGS. 1A to 1D are cross-sectional views sequentially illustrating the conventional process of forming a circuit pattern on a PCB;

FIG. 2 is a flowchart illustrating the process of forming a circuit pattern on a PCB, according to a first embodiment of the present invention;

FIGS. 3A to 3E are cross-sectional views sequentially illustrating the process of forming the circuit pattern on the PCB, according to the first embodiment of the present invention;

FIG. 4A is a cross-sectional view illustrating the grooved plate, according to a second embodiment of the present invention; and

FIG. 4B is a cross-sectional view illustrating the grooved plate, according to a third embodiment of the present invention.

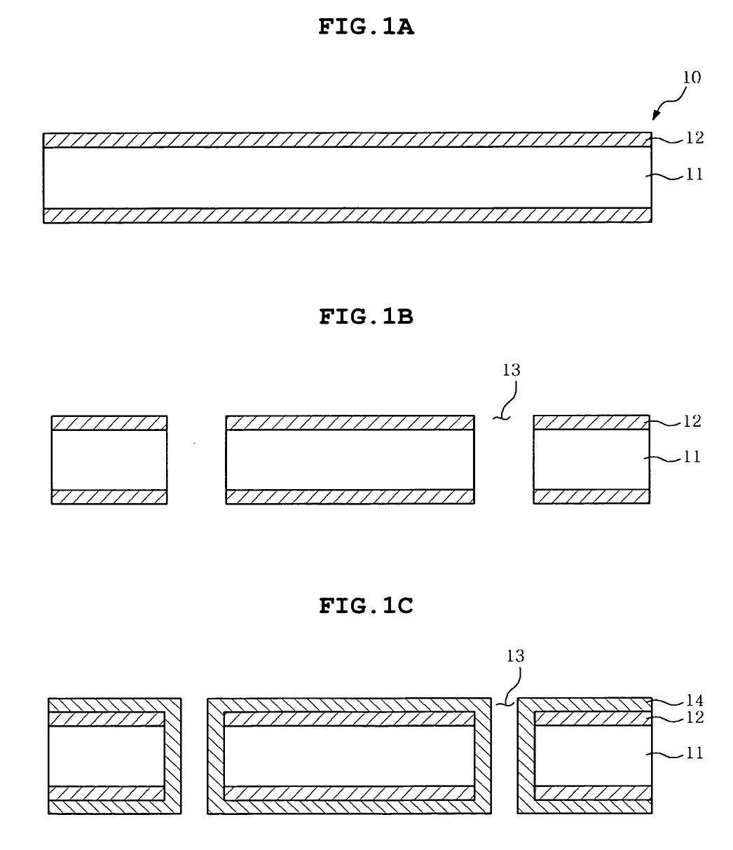

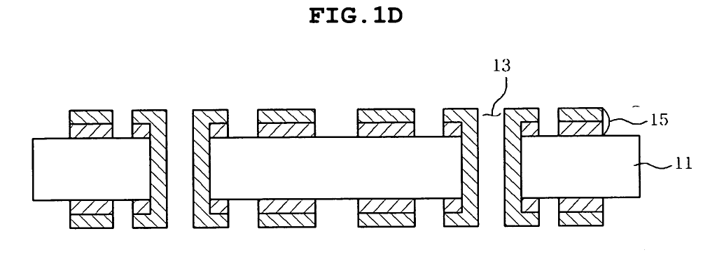

### DESCRIPTION OF THE PREFERRED EMBODIMENTS

Hereinafter, a detailed description will be given of the preferred embodiments of the present invention, with reference to the appended drawings.

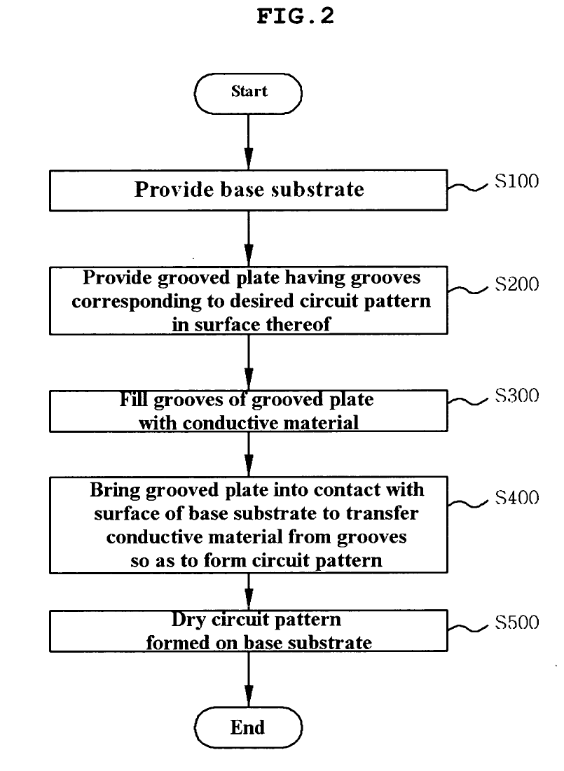

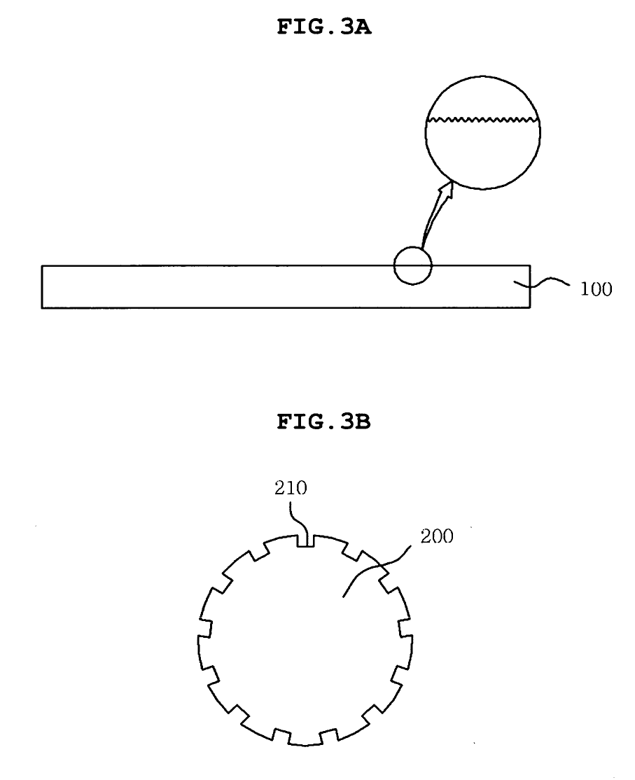

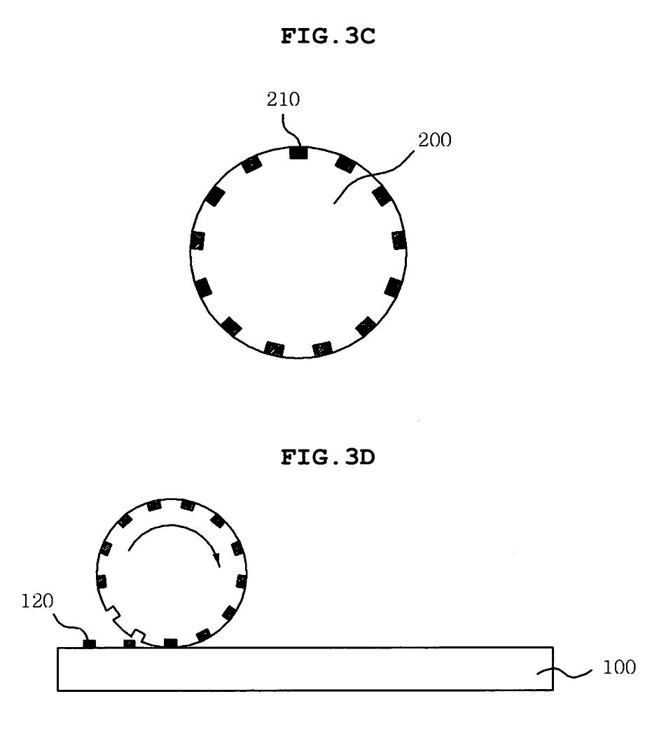

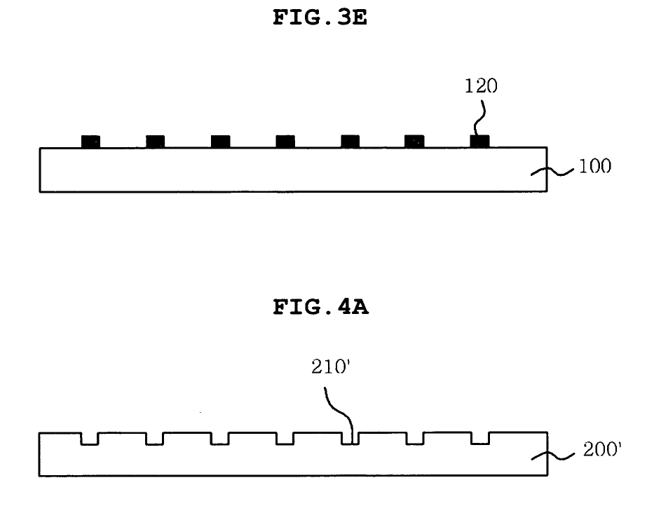

FIGS. 2 and 3A to 3E illustrate the process of forming a circuit pattern on a PCB, according to a first embodiment of the present invention.

As such, FIG. 2 is a flowchart illustrating the process of forming the circuit pattern on the PCB according to the first embodiment of the present invention, and FIGS. 3A to 3E are cross-sectional views sequentially illustrating the process of forming the circuit pattern on the PCB according to the first embodiment of the present invention.

Referring to FIG. 2, the method of forming the circuit pattern on the PCB, according to the first embodiment of the present invention, is described.

First, a base substrate is provided (S100).

As such, the base substrate preferably comprises an insulating layer having a predetermined surface roughness or a seed layer thereon, such that adhesion between the base substrate and the conductive material for a circuit pattern is increased to ensure easy transfer of the conductive material.

Further, the insulating layer may be imparted with a predetermined surface roughness by performing a chemical etching process or a plasma etching process on the insulating layer.

The seed layer is preferably formed through electroless plating using a metal different from that of the metal particles included in the conductive material for a circuit patter.

Alternatively, the base substrate may have at least one circuit pattern therein.

Thereafter, a grooved plate, having grooves corresponding to a desired circuit pattern in the surface thereof, is provided (S200).

The grooved plate may be formed by subjecting a material that is stronger than the base substrate, for example, a metal or an alloy, to an etching process, a physical process or a laser process, to thus form grooves corresponding to a desired circuit pattern.

The grooved plate may be in the shape of a hollow cylinder or a solid cylinder or of a flat plate. As such, the cylinder or the flat plate may be used as it is, or may be used in a state in which the flat plate is wound on a cylindrical shaft or which the hollow cylinder is fitted onto a cylindrical shaft.

Then, the grooves of the grooved plate are filled with a conductive material (S300).

The conductive material preferably comprises viscous liquid, including metal particles and an epoxy resin binder.

In this case, in order to fill the grooves of the grooved plate with the conductive material, a sequence of filling the grooves with the conductive material using a squeeze and then scraping the surface of the grooved plate using a thin blade may be performed. Alternatively, a process of loading the conductive material into respective grooves may be useful.

Then, the grooved plate is brought into contact with the surface of the base substrate to thus transfer the conductive material from the grooves, consequently forming the circuit pattern (S400).

That is, the grooved plate is brought into contact with the base substrate and predetermined heat and/or pressure are applied thereto, whereby the conductive material is transferred from the grooves to the surface of the base substrate, consequently forming a desired circuit pattern.

Finally, the circuit pattern formed on the base substrate is dried (S500).

The drying process includes, for example, room temperature drying, hot air drying, heat transfer drying, far infrared drying, and UV drying.

FIGS. 3A to 3E sequentially illustrate the process of forming the circuit pattern on the PCB, according to the first embodiment of the present invention.

As illustrated in FIG. 3A, a base substrate 100, on which a circuit pattern is formed, is provided.

The base substrate 100 has formed thereon an insulating layer having a predetermined surface roughness for increasing the adhesion between the base substrate 100 and the conductive material for a circuit pattern, so as to easily transfer the conductive material to the surface of the base substrate 100.

For example, the surface of the insulating layer may be roughened using a chemical etching process or a plasma etching process.

The chemical etching process is a technique in which a swelling process for applying a predetermined temperature to increase the area of the insulating layer is performed, and then part of the surface of the insulating layer having the increased area is melted off using a chemical. As the chemical, permanganic acid, sulfuric acid, chromium, etc., may be used.

The plasma etching process is a technique in which gas particles accelerated by electrical energy collide with the surface of the insulating layer to thus break and remove the polymer chain on such a surface, not through a chemical reaction but through a physical reaction, thereby roughening the surface of the insulating layer.

Alternatively, the seed layer may be formed on the base substrate to thus further increase the adhesion between the base substrate and the conductive material for a circuit pattern. The seed layer is preferably formed through electroless plating using a metal different from that of the metal particles included in the conductive material.

In addition, the base substrate may be formed to include at least one circuit pattern therein.

As illustrated in FIG. 3B, a grooved plate 200 having grooves 210 corresponding to a desired circuit pattern in the surface thereof is provided.

The grooved plate 200 is formed in the shape of a cylinder using a material such as a metal or an alloy which is harder than the base substrate 100 and is not affected by predetermined heat or pressure.

The groove 210 may be formed in the surface of the grooved plate 200 in a shape corresponding to a desired circuit pattern grooved plate using an etching process, a physical process, or a laser process. Such a physical process is performed using an instrument such as a knife or a drill and physical force.

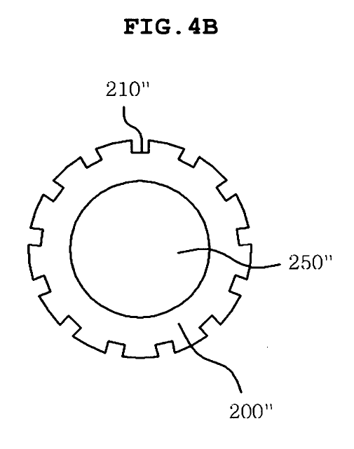

According to a second embodiment of the present invention, as illustrated in FIG. 4A, a grooved plate 200′ which is in a flat plate shape and has grooves 210′ formed therein is used as it is, or a grooved plate 200′ may be used in a state of being wound on a cylindrical shaft (not shown).

According to a third embodiment of the present invention, as illustrated in FIG. 4B, a grooved plate 200″, which is in the shape of a hollow cylinder, may be used in a state in which it is fitted onto a cylindrical shaft 250″. In this way, since the grooved plate 200″ fitted onto such a cylindrical shaft 250″ may be replaced with a new one, it is possible to realize low cost and easy storage.

As illustrated in FIG. 3C, the grooves 210 of the grooved plate 200 are filled with a conductive material 300.

The conductive material 300 is viscous liquid including metal particles and an epoxy resin binder, and may comprise silver, copper, nickel, platinum, tin, or gold. Here, the type of conductive material 300 may vary depending on the material for the base substrate 100 on which the circuit pattern is formed.

As the process of filling the grooves 210 of the grooved plate 200 with the conductive material 300, a sequence of filling the surface of the grooved plate 200 with a conductive material 300 using a squeeze and then scraping the surface of the grooved plate 200 using a thin blade may be performed such that the conductive material 300 remains only in the grooves 210. In addition, a process of loading a conductive material 300 into respective grooves 210 without the need for a polishing process may be applied.

As illustrated in FIG. 3D, the grooved plate 200 is brought into contact the surface of the base substrate 100, thus forming a circuit pattern 120.

That is, portions of the grooved plate 200 are sequentially brought into contact with the surface of the base substrate 100, and then predetermined heat and/or pressure is applied to thus transfer the conductive material from the grooves 210 to the surface of the base substrate 100, consequently forming the circuit pattern 120.

As mentioned above, the circuit pattern 120 can be formed on the surface of the base substrate 100 using the grooved plate 200 having the grooves 210 corresponding to the circuit pattern, and therefore a light, slim, short and small product can be obtained while realizing fineness of the circuit pattern and maintaining the reliability of the product.

Finally, as illustrated in FIG. 3E, the circuit pattern 120 formed on the base substrate 100 is dried, thereby completing the circuit pattern 120.

Although the circuit pattern 120 formed of the conductive material 300, which is viscous liquid, may be naturally dried, an additional drying process may be performed to increase the process speed and prevent the widening of the circuit pattern 120.

Examples of the drying process include room temperature drying, hot air drying, heat transfer drying, far infrared drying, and UV drying.

The conventional method of forming the circuit pattern on the PCB comprises applying the photosensitive material on the upper surface of a copper foil, attaching an artwork film having a predetermined pattern, performing exposure and development to thus form an etching resist pattern, and performing an etching process. Thus, a large number of processes for forming the circuit pattern is required, and also defect rates are increased due to over-etching or under-etching of the copper foil for use in the formation of the circuit pattern, undesirably causing the deformation of the circuit pattern, resulting in unreliable products.

However, in the method of forming the circuit pattern on the PCB according to the present invention, the grooved plate having grooves corresponding to a desired circuit pattern in the surface thereof is filled with the conductive material, after which portions thereof are sequentially brought in contact with the surface of the base substrate, to thus transfer the conductive material from the grooves to the surface of the base substrate, consequently forming the circuit pattern. Thereby, the manufacturing cost is decreased and product competitiveness is improved, thanks to the simple circuit pattern formation process.

Moreover, a desired circuit pattern can be easily formed using the grooves of the grooved plate, thereby assuring the reliability of the product and realizing a fine circuit pattern and light, slim, short and small products.

As described hereinbefore, the present invention provides a method of forming a circuit pattern on a PCB. According to the method of forming the circuit pattern on the PCB of the present invention, the circuit pattern can be formed using the grooved plate having grooves corresponding to a desired circuit pattern in the surface thereof, thus realizing a fine circuit pattern and a light, slim, short and small product, and assuring the reliability of the product.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of forming a circuit pattern on a printed circuit board, comprising:
(A) providing a base substrate;
(B) providing a grooved plate having grooves corresponding to a predetermined circuit pattern in a surface thereof;
(C) filling the grooves of the grooved plate with a conductive material; and
(D) bringing the grooved plate into contact with a surface of the base substrate to thus transfer the conductive material from the grooves, consequently forming the circuit pattern.

2. The method as set forth in claim 1, wherein the base substrate comprises an insulating layer having a predetermined surface roughness thereon, so that the conductive material is easily transferred thereto.

3. The method as set forth in claim 1, wherein the base substrate comprises a seed layer thereon, so that the conductive material is easily transferred thereto.

4. The method as set forth in claim 3, wherein the seed layer is formed through electroless plating.

5. The method as set forth in claim 1, wherein the grooved plate is formed using a material having strength greater than the base substrate.

6. The method as set forth in claim 1, wherein the grooved plate is in a shape of a cylinder.

7. The method as set forth in claim 1, wherein the grooved plate is in a shape of a flat plate.

8. The method as set forth in claim 1, wherein the conductive material is liquid that contains metal particles.

9. The method as set forth in claim 1, further comprising (E) drying the circuit pattern formed on the base substrate, after the (D).

10. The method as set forth in claim 1, wherein the grooves of the grooved plate in the (B) are formed through an etching process.

11. The method as set forth in claim 1, wherein the grooves of the grooved plate in the (B) are formed through a physical process.

12. The method as set forth in claim 1, wherein the grooves of the grooved plate in the (B) are formed through a laser process.

13. The method as set forth in claim 1, wherein the (D) is performed by applying predetermined heat and/or pressure to the grooved plate to thus easily transfer the conductive material from the grooves to at least one surface of the base substrate.
